(19) United States
(12) Patent Application Publication
(10) Pub. No.: US 2009/0059543 A1
(43) Pub. Date: Mar. 5, 2009

(54) ELECTRONIC DEVICE MANUFACTURING METHOD USING LDS AND ELECTRONIC DEVICE MANUFACTURED BY THE METHOD

(75) Inventors: Ick-Sung CHOE, Yongin-si (KR); Hyun-Jung JEONG, Seongnam-si (KR); Young-Ki KIM, Yongin-si (KR); Shin-Chul KANG, Seoul (KR); Soon-Min HONG, Seoul (KR); Se-Young JANG, Yongin-si (KR); Jae-Chul JIN, Suwon-si (KR); Gyun HEO, Seoul (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 12/204,262

(22) Filed: Sep. 4, 2008

(30) Foreign Application Priority Data
Sep. 5, 2007 (KR) 10-2007-0089940

(51) Int. Cl. H05K 5/00; B29C 35/08

(52) U.S. Cl. 361/752; 264/401

(57) ABSTRACT

Disclosed is a method for manufacturing an electronic device using LDS and an electronic manufacturing by the method, in which resin for LDS is adhered to an inner surface of an external case by double injection or insert injection so as to implement a circuit. The electronic device using LDS includes upper and lower external cases, wherein resin for LDS is adhered to an inner surface of the lower external case by double injection or insert injection. Components of the electronic device are mounted on the resin, and the upper and lower external case are assembled with each other.

### CROSS REFERENCE TO RELATED APPLICATION

This application claims priority from and the benefit of Korean Patent Application No. 10-2007-0089940, filed on Sep. 5, 2007, which is hereby incorporated by reference for all purposes as if fully set forth herein.

### BACKGROUND OF THE INVENTION

1. Field of the Invention

The present invention relates to an electronic device manufacturing method using laser direct structuring (LDS) and an electronic device manufactured by the method, in which resin for LDS is adhered to an inner surface of an external case of an electronic device by double injection or insert injection to implement a circuit.

2. Discussion of the Background

In general, one method of minimizing the size of an electronic product is to optimize the arrangement of its components. That is, the size of an electronic product may be reduced by optimizing the arrangement of parts mounted on a printed circuit board and optimizing the arrangement of parts that have a large volume and occupy the interior of a case, (for example, a battery, a camera module, a keypad, a display unit, various kinds of connectors, etc.) of a finished product.

However, there is a limit to the amount by which the size may be reduced by optimally arranging the parts having a large volume. Therefore, there has recently been a tendency to reduce the size of a product by mounting parts in an external case of the product.

One method for mounting parts in an external case of the product is the Mold Interconnected Device (MID) method. The MID method includes a Laser Direct Structuring (LDS) method, a Microscopic Integrated Processing Technology (MIPTEC) method, an ink transcription method, a photo imaging method, and a Hot Embossing method.

The above mentioned methods each include one injection process.

Moreover, there is a PCK method and SKW method, which each include two injection processes.

In the MIPTEC method, resin undergoes a plasma process and is entirely plated with non-electrolytic copper. Then, electro plating is performed on the resin after unnecessary portions are cut off with a laser, so that only a necessary portion is included in a circuit. However, this method has a disadvantage in that the manufacturing cost may be high.

In the ink transcription method, a desired shape is formed on rubber, and the shape on the rubber is covered with ink and stamped on the resin. However, there is a disadvantage in that a poor circuit may be formed.

In the photo imaging method, the entire resin is plated, and a necessary portion is covered by a mask and etched to form a circuit. However, there may be limitations regarding the arrangement of the circuit within a device.

In the Hot Embossing method, a circuit is formed using a conductive film and is bonded to resin. However, the cost of modifying the circuit may be high.

In the PCK method, a circuit is formed using a resin, which is mixed with Pd to absorb metal, as a first injection resin and using a mask as a second injection resin. However, the cost of modifying the circuit may be high.

In the SKW method, Pd is absorbed into a first injection resin so that the resin is formed in a state where metal can be absorbed. Then, a circuit is formed using a mask as a second injection resin. A plated circuit is formed at a portion where the first injection resin is exposed because a second injection resin is opened. However, the cost of modifying the circuit may be high.

Herein, the most popular method is the LDS method. The reason why this method is popular is that, in comparison with other techniques, the cost of developing/producing costs of a product is low, a fine circuit may be implemented, and the circuit may be easily modified.

However, the conventional LDS method has a disadvantage in that the number of types of resins that may be used is limited, and a resin may be easily broken because the strength of the resin may decrease due to a filler required in an LDS, which may reduce the reliability of a product. Therefore, the LDS method has not been applied to an external case of a portable communication device requiring high reliability.

### SUMMARY OF THE INVENTION

The present invention provides an electronic device manufacturing method using LDS and an electronic device manufactured by the method, in which the strength of the resin for LDS may be improved.

The present invention also provides an electronic device manufacturing method using LDS and an electronic device manufactured by the method, in which the quality of a surface and coating property of an external case of the electronic device may be improved, and in which costs may be reduced because a resin for LDS may be injected only to a necessary portion.

The present invention also provides an electronic device manufacturing method using an LDS and an electronic device manufactured by the method, which may allow a circuit to be implemented such that the size of a printed circuit board is reduced in such a manner that components on a conventional printed circuit board are moved to an external case, and thus a product may be thinner and the size thereof may be reduced.

Additional features of the invention will be set forth in the description which follows, and in part will be apparent from the description, or may be learned by practice of the invention.

The present invention discloses an electronic device using LDS. The device includes upper and lower external cases, and a resin for LDS is adhered to an inner surface of the lower external case by double injection or insert injection. Components of the electronic device are mounted on the resin, and the upper and lower external cases are assembled with each other.

The present invention also discloses a method for manufacturing an electronic device using LDS. The method includes forming upper and lower external cases of an electronic device by injection forming, adhering resin for LDS to an inner surface of the lower external case by double injection, forming an intenna in the resin by an LDS scheme, forming a printed circuit, mounting components of the electronic device in the lower external case, assembling a connecting pin of a printed circuit board (PCB) with the lower external case, mounting the PCB in the lower external case so that the PCB is assembled with the connecting pin, and assembling the upper external case and the lower external case with each other.

The present invention also discloses a method for manufacturing an electronic device using LDS. The method includes injecting a resin for LDS, forming a printed circuit on a surface of the resin for an LDS, adhering the resin to an inner surface of a lower external case of the electronic device by insert injection, mounting components of the electronic device, a connecting pin of a PCB, and the PCB in the lower external case, and assembling the upper external case and the lower external case with each other, which are formed through injection forming.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is an exploded sectional view of an electronic device using LDS according to a first exemplary embodiment of the present invention, in which a procedure of manufacturing the electronic device through double injection is shown.

FIG. 2 is a flow chart showing a method of manufacturing an electronic device using LDS through double injection according to the first exemplary embodiment of the present invention.

FIG. 3 is an exploded sectional view of an electronic device using LDS according to a second exemplary embodiment of the present invention, in which a procedure of manufacturing the electronic device through insert injection is shown.

FIG. 4 is a flow chart showing a method of manufacturing an electronic device using LDS through insert injection according to the second exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. Like reference numerals in the drawings denote like elements.

Hereinafter, exemplary embodiments of the present invention will be described with reference to the accompanying drawings.

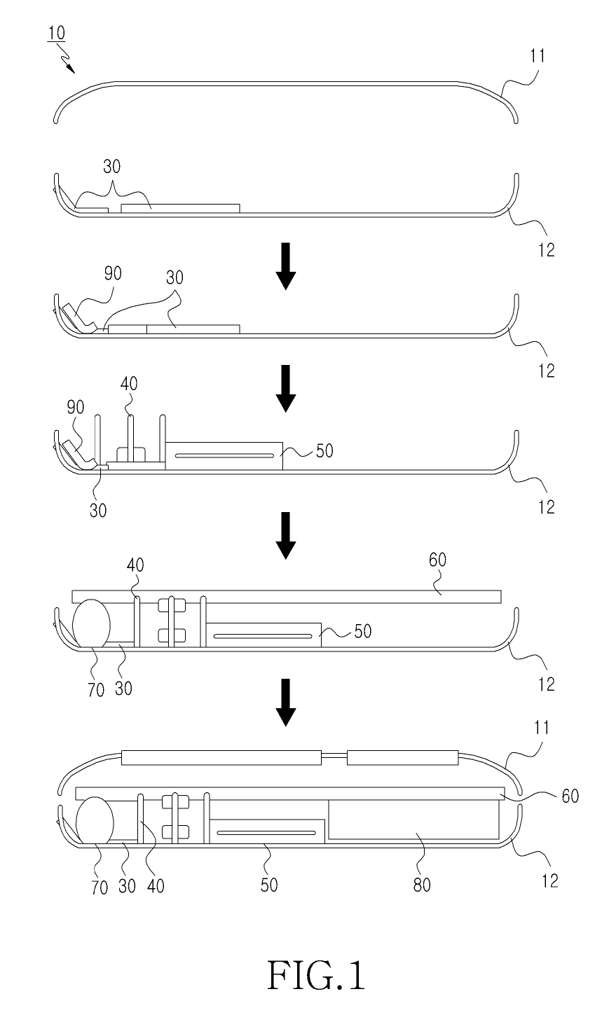

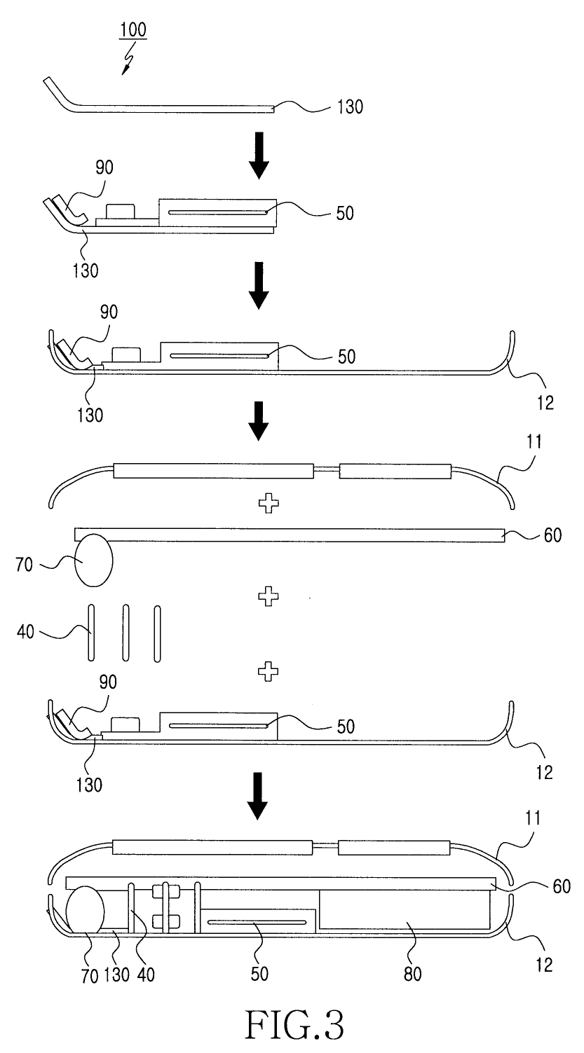

FIG. 1 and FIG. 3 show an electronic device 10 and 100, respectively, using Laser Direct Structuring (LDS) that includes upper and lower external cases 11 and 12. Resin 30 and 130 for LDS is adhered to an inner surface of the upper and lower external cases 11 and 12 by double injection or insert injection.

Herein, the resin 30 and 130 for an LDS is adhered to a part of the interior or the entire interior of the lower external case 12 by double injection or insert injection.

A printed circuit, on which components (e.g. a camera module 70) of an electronic device and an intenna 90 are mounted, is formed by performing an LDS method on the resin 30 and 130. Component of the electronic device is mounted on the resin 30 and 130, which is adhered to the lower external case 12, and a small-sized printed circuit board 60 is mounted thereon.

In this state, the lower external case 12 includes an earphone jack 50, an external connecting port (not shown), and other hardware components (not shown).

In this state, the upper external case 11 is assembled with the lower external case 12.

Here, the electronic device is a portable communication device.

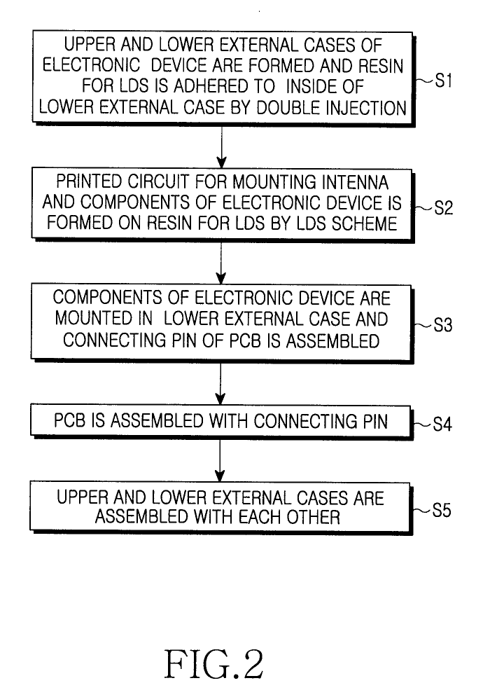

Hereinafter, the procedure of a method for manufacturing an electronic device using LDS, which has the above described structure, according to the first exemplary embodiment of the present invention will be described in more detail with reference to FIG. 1 and FIG. 2.

As shown in FIG. 1 and FIG. 2, according to the method for manufacturing an electronic device 10 through double injection, firstly, upper and lower external cases 11 and 12 of the electronic device 10 are formed by an injection forming method, and resin 30 for LDS is attached to an inside of the lower external case 12 through double injection (S1). Double injection includes a first injection step and a second injection step.

The resin 30 may have an adhesive property.

A printed circuit, on which an intenna 90 or components (e.g. a camera module 70) of the electronic device are mounted, is formed on the resin 30 (S2).

Components of the electronic device are mounted in the lower external case 12, and are assembled with a connecting pin 40 of the PCB 60 (S3).

At this time, an earphone jack 50, an external connecting port (not shown), and other hardware components (not shown) are included in the lower external case 12. Herein, it may be possible to mount a plurality of components in the lower external case 12.

The size-reduced PCB 60 is assembled with the connecting pin 40 so that it is mounted in the lower external case 12 (S4).

The upper external case 11 and the lower external case 12 are assembled with each other (S5).

The resin 30 may be adhered to a portion of the inner surface or the entire inner surface of the lower external case 12 by double injection. As such, the resin 30 may be double injected only into a portion of the lower external case 12 necessary for a circuit so that the amount of resin 30 may be reduced. As a result, the cost of manufacturing a product may be decreased.

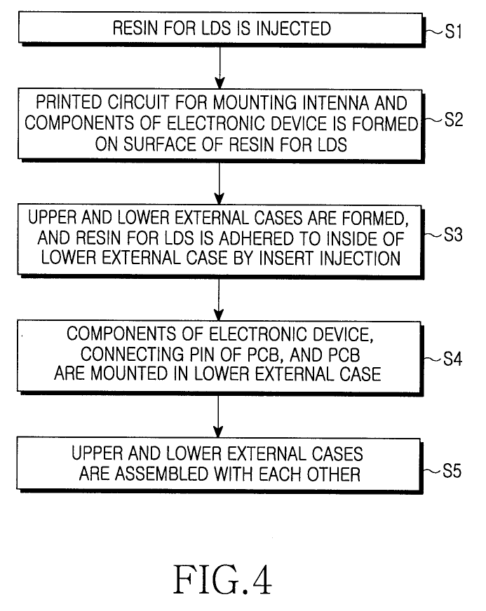

Referring to FIG. 3 and FIG. 4, a method for manufacturing an electronic device using an LDS, which has the above-described structure, according to a second exemplary embodiment of the present invention, will be described in more detail below.

As shown in FIG. 3 and FIG. 4, according to a method for manufacturing an electronic device 100 through insert injection, a resin 130 for LDS is injected (S1). Insert injection includes a first injection step and an insert injection step.

A printed circuit, on which an intenna 90 and components of an electronic device are mounted, is formed on a surface of the resin 130 (S2).

Upper and lower cases 11 and 12 of an electronic device are formed by injection, and the resin 130 is adhered to an inner surface of the lower external case 12 through insert injection (S3).

The resin 130 may have an adhesive property.

The resin 130 may be adhered to a portion of the inner surface or the entire inner surface of the lower external case 12 through insert injection. As such, the resin 130 can be injected and inserted into only a portion within the lower external case 12 that is necessary to form a circuit so that the amount of resin 30 may be reduced. As a result, the cost of manufacturing a product may be decreased.

Components (e.g. a camera module 70) of an electronic device and a connecting pin 40 are mounted on a PCB 60, and the PCB 60 is mounted in the lower external case 12 (S4).

At this time, an earphone jack 50 and a plurality of components are mounted in the lower external case 12.

The upper external case 11 and the lower external case 12 are assembled with each other (S5).

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An electronic device using laser direct structuring (LDS), the device comprising:
an upper external case; and
a lower external case,
wherein resin for an LDS is adhered to an inner surface of the lower external case by double injection or insert injection, components of the electronic device are mounted on the resin, and the upper external case and the lower external case are assembled with each other.

2. The electronic device of claim 1, wherein the lower external case comprises an intenna, an earphone jack, and an external connecting port.

3. The electronic device of claim 1, wherein the resin is an adhesive resin.

4. The electronic device of claim 1, wherein the resin covers the entire inner surface of the lower external case.

5. A method for manufacturing an electronic device using laser direct structuring (LDS), the method comprising:
forming an upper external case and a lower external case of an electronic device by injection forming;
adhering resin for LDS to an inner surface of the lower external case by double injection;
forming an intenna on the resin by an LDS scheme and forming a printed circuit;
mounting components of the electronic device in the lower external case;
assembling a connecting pin of a printed circuit board (PCB) with the lower external case;
mounting the PCB in the lower external case so that the PCB is assembled with the connecting pin; and
assembling the upper external case and the lower external case with each other.

6. The method of claim 5, wherein the lower external case comprises an earphone jack, and an external connecting part.

7. The method of claim 5, wherein the resin is an adhesive resin.

8. The method of claim 5, wherein the resin covers the entire inner surface of the lower external case.

9. A method for manufacturing an electronic device using laser direct structuring (LDS), the method comprising:
injecting a resin for an LDS;
forming a printed circuit on a surface of the resin;
adhering the resin to an inner surface of a lower external case of the electronic device by insert injection;
mounting components of the electronic device, a connecting pin of a printed circuit board (PCB), and the PCB in the lower external case; and
assembling the upper external case and the lower external case with each other, the upper external case and the lower external case being formed through injection forming.

10. The method of claim 9, wherein the lower external case comprises an earphone jack, and an external connecting port.

11. The method of claim 9, wherein the resin is an adhesive resin.

12. The method of claim 9, wherein the resin is adhered to the entire inner surface of the external case by insert injection.
